(19) United States
(12) Patent Application Publication
(10) Pub. No.: US 2024/0030678 A1
(43) Pub. Date: Jan. 25, 2024

(54) SEMICONDUCTOR LASER DEVICE

(71) Applicant: HAMAMATSU PHOTONICS K.K., Hamamatsu-shi, Shizuoka (JP)

(72) Inventors: Nobutaka SUZUKI, Hamamatsu-shi, Shizuoka (JP); Naota AKIKUSA, Hamamatsu-shi, Shizuoka (JP); Tadataka EDAMURA, Hamamatsu-shi, Shizuoka (JP)

(73) Assignee: HAMAMATSU PHOTONICS K.K., Hamamatsu-shi, Shizuoka (JP)

(21) Appl. No.: 18/033,623

(22) PCT Filed: Jul. 15, 2021
(86) PCT No.: PCT/JP2021/026685

§ 371 Date: Apr. 25, 2023

(30) Foreign Application Priority Data
Nov. 4, 2020 (JP) 2020-184269

(51) Int. Cl. H01S 5/024; H01S 5/34; H01S 5/02315

(52) U.S. Cl. CPC H01S 5/02423; H01S 5/3401; H01S 5/02315

(57) ABSTRACT

In a semiconductor laser device, a supply path that guides a cooling fluid supplied from a supply port side, toward a disposition region, spray holes that spray the cooling fluid guided by the supply path, from below the disposition region, and a discharge path that guides the cooling fluid sprayed from the spray holes, toward a discharge port are provided within a body portion of a heat sink. The spray holes are disposed along a resonance direction of a semiconductor laser element disposed in the disposition region, and the discharge path extends in a direction intersecting with the resonance direction of the semiconductor laser element disposed in the disposition region.

### TECHNICAL FIELD

The present disclosure relates to a semiconductor laser device.

### BACKGROUND ART

In the related art, for example, a semiconductor laser device including a heat sink has been described in Patent Literature 1. The heat sink described in Patent Literature 1 includes a first conductive flat plate having an upper surface in which a first recessed portion is formed; a second conductive flat plate having a lower surface in which a second recessed portion is formed and an upper surface on which a semiconductor laser element is mounted; and a conductive partition plate having a lower surface covering the first recessed portion, an upper surface covering the second recessed portion, and one or more through-holes that allow the first recessed portion to communicate with the second recessed portion. A refrigerant inlet extends from one of the first recessed portion and the second recessed portion, and allows a refrigerant to flow into the heat sink. A refrigerant outlet extends from the other of the first recessed portion and the second recessed portion, and allows the refrigerant to flow out from the heat sink.

### CITATION LIST

### Patent Literature

Patent Literature 1: Japanese Unexamined Patent Publication No. 2006-352019

### SUMMARY OF INVENTION

### Technical Problem

In the semiconductor laser device described above, the improvement in cooling efficiency of the semiconductor laser element by the heat sink is an important factor. To improve the cooling efficiency of the semiconductor laser element, it is necessary to devise a configuration of a series of internal paths from a supply port to a discharge port for a cooling fluid in the heat sink. For example, it is also considered that a laser element having relatively long resonator length and relatively large amount of heat generated, such as a quantum cascade laser element, is mounted on the semiconductor laser device. For this reason, it is important to examine the configuration of the series of internal paths in the heat sink while taking into account a disposition mode of the semiconductor laser element.

The present disclosure is conceived to solve the foregoing problems, and an object of the present disclosure is to provide a semiconductor laser device in which the cooling efficiency of a semiconductor laser element by a heat sink is improved.

### Solution to Problem

According to one aspect of the present disclosure, there is provided a semiconductor laser device including: a semiconductor laser element; and a heat sink that cools the semiconductor laser element. The heat sink includes a body portion which has a surface with a disposition region where the semiconductor laser element is disposed, and in which a supply port for supplying a cooling fluid and a discharge port for discharging the cooling fluid are provided apart from the disposition region. A supply path that guides the cooling fluid supplied from a supply port side, toward the disposition region, spray holes that spray the cooling fluid guided by the supply path, from below the disposition region, and a discharge path that guides the cooling fluid sprayed from the spray holes, toward the discharge port are provided within the body portion. In a plan view of the heat sink, the spray holes are disposed along a resonance direction of the semiconductor laser element disposed in the disposition region. In a plan view of the heat sink, the discharge path extends in a direction intersecting with the resonance direction of the semiconductor laser element disposed in the disposition region.

In the semiconductor laser device, the spray holes are disposed along the resonance direction of the semiconductor laser element disposed in the disposition region. For this reason, even when the resonator length of the semiconductor laser element is relatively long, the cooling fluid can be sprayed from the spray holes toward the disposition region with a length corresponding to the resonator length. In addition, in the semiconductor laser device, the discharge path extends in the direction intersecting with the resonance direction of the semiconductor laser element disposed in the disposition region. Accordingly, the distance by which the cooling fluid, which has received heat from the disposition region, flows below the disposition region can be kept small. As described above, in the semiconductor laser device, the cooling efficiency of the semiconductor laser element by the heat sink is improved.

The heat sink may have a rectangular shape having long sides and short sides in a plan view, and the resonance direction of the semiconductor laser element disposed in the disposition region may extend along the short sides of the heat sink. By aligning the resonance direction of the semiconductor laser element with the short sides of the heat sink, the structure of disposition of the semiconductor laser element with respect to the heat sink can be simplified. In addition, relatively large space can be secured in a long side direction of the heat sink, and even when the resonator length of the semiconductor laser element is lengthened, a disposition space for a sealing member that seals flow paths of the cooling fluid, or the like can be easily secured.

The spray holes may be formed of a plurality of round holes. In this case, the pressure of the cooling fluid to be sprayed from the spray holes can be sufficiently increased, and the cooling efficiency of the semiconductor laser element can be further improved.

A gold plating may be applied to an inner wall of each spray hole. In this case, the ionization of the inner walls of the spray holes caused by the cooling fluid can be prevented by the gold plating. Accordingly, the pressure of the cooling fluid to be sprayed from the spray holes can be prevented from decreasing due to an increase in the diameter of the spray holes over time.

In a plan view of the heat sink, the supply path may extend in a direction intersecting with a disposition direction of the spray holes. Accordingly, the pressure of the cooling liquid to be sprayed from the spray holes is made uniform.

A spacer disposed adjacent to the heat sink may be provided, and an electrode lead electrically connected to the semiconductor laser element may be disposed between the heat sink and the spacer. In this case, since the electrode lead can be disposed close to the semiconductor laser element, current pulses with a fast rise time can be injected to the semiconductor laser element with low loss. Therefore, a short-pulse operation of the semiconductor laser element can be realized.

A dummy bar disposed alongside the semiconductor laser element disposed in the disposition region and extending in the resonance direction of the semiconductor laser element may be provided. In this case, the stability of the posture of the heat sink or the like can be increased.

The semiconductor laser element may be a quantum cascade laser element. According to the configuration of the semiconductor laser device, even when the quantum cascade laser element having relatively long resonator length and relatively large amount of heat generated is disposed in the disposition region, cooling by the heat sink can be efficiently performed.

### Advantageous Effects of Invention

According to the present disclosure, the cooling efficiency of the semiconductor laser element by the heat sink is improved.

### BRIEF DESCRIPTION OF DRAWINGS

FIG. 1 is a perspective view illustrating a semiconductor laser device according to one embodiment of the present disclosure.

FIG. 2 is an exploded perspective view illustrating a structure including a semiconductor laser element and a heat sink.

FIG. 3 is a front view of the structure illustrated in FIG. 2.

FIG. 4 is a perspective view of the heat sink.

FIG. 5 is a plan view illustrating a first layer of the heat sink.

FIG. 6 is a plan view illustrating a second layer of the heat sink.

FIG. 7 is a plan view illustrating a third layer of the heat sink.

FIG. 8 is a main part enlarged plan view illustrating a disposition relationship between the heat sink and the semiconductor laser element.

FIG. 9 is a main part enlarged cross-sectional view illustrating the disposition relationship between the heat sink and the semiconductor laser element.

FIG. 10 is a front view illustrating a modification example of the structure including the semiconductor laser element and the heat sink.

FIG. 11 is a main part enlarged plan view illustrating a modification example of the heat sink.

### DESCRIPTION OF EMBODIMENTS

Hereinafter, an exemplary embodiment of a semiconductor laser device according to one aspect of the present disclosure will be described in detail with reference to the drawings.

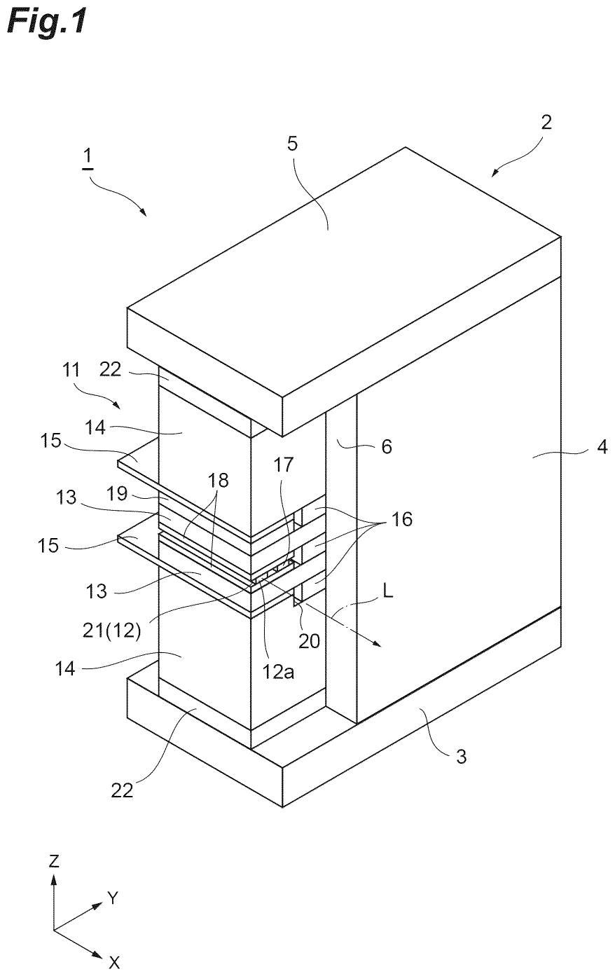

FIG. 1 is a perspective view illustrating a semiconductor laser device according to one embodiment of the present disclosure. As illustrated in FIG. 1, a semiconductor laser device 1 has a configuration in which a structure 11 including a semiconductor laser element 12 and a heat sink 13 is supported by a holder 2. In the following description, an emission direction of laser light L from the semiconductor laser element 12 is an X direction, a direction orthogonal to the X direction in a horizontal plane of FIG. 1 is a Y direction, and a stacking direction of components in the structure 11 is a Z direction. A viewpoint from the Z direction corresponds to a plan view in the present disclosure.

The holder 2 is formed of a bottom plate 3, a side plate 4, and a top plate 5. Examples of the forming material for the holder 2 include, for example, aluminum, a stainless steel (SUS). When viewed in the Z direction, the bottom plate 3 and the top plate 5 have a rectangular shape with short sides in the X direction and long sides in the Y direction. The bottom plate 3 is provided with a supply port for supplying a cooling fluid R to be described later to the structure 11 and with a discharge port for discharging the cooling fluid R from the structure 11 (both the supply port and the discharge port of the bottom plate 3 are not illustrated). The side plate 4 has a rectangular shape and is disposed to connect edge portions on one long side of the bottom plate 3 and the top plate 5. The height of the side plate 4 corresponds to the height of the structure 11. The structure 11 is sandwiched by the bottom plate 3 and the top plate 5 in the stacking direction of the components.

The length in the Y direction of the side plate 4 is smaller than the length of the long sides of the bottom plate 3 and the top plate 5. When the holder 2 is viewed in the X direction, the structure 11 is disposed aligned with one short sides of the bottom plate 3 and the top plate 5, and the side plate 4 is disposed aligned with the other short sides of the bottom plate 3 and the top plate 5. Due to the offset presence of the side plate 4, a cutout portion 6 that exposes a part (portion including an emitting surface 12a of the semiconductor laser element 12) on one surface side of the structure 11 when viewed in the X direction is formed in the holder 2. The laser light L emitted from the emitting surface 12a of the semiconductor laser element 12 is emitted through the cutout portion 6 in the X direction.

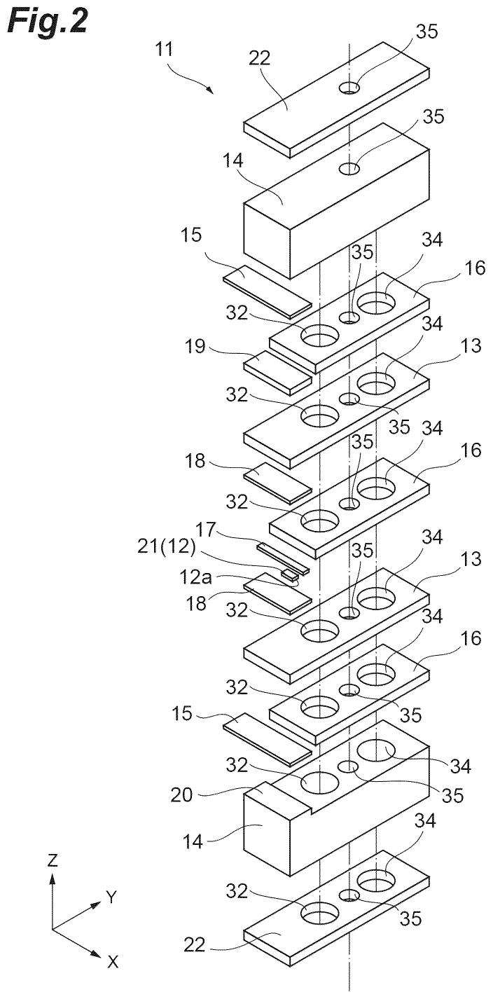

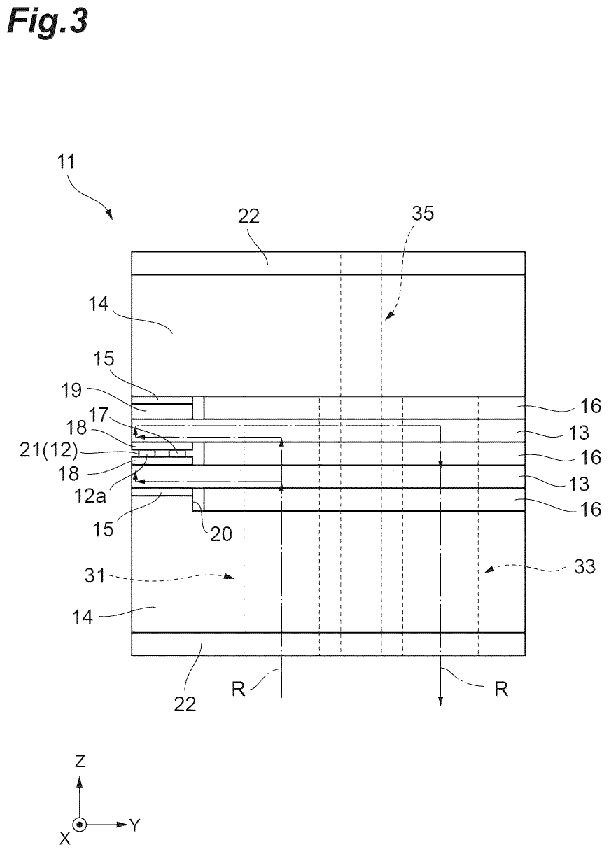

FIG. 2 is an exploded perspective view illustrating the structure including the semiconductor laser element and the heat sink. FIG. 3 is a front view of the structure illustrated in FIG. 2. As illustrated in FIGS. 2 and 3, the structure 11 includes the semiconductor laser element 12, a pair of upper and lower heat sinks 13 and 13, a pair of upper and lower spacers 14 and 14, a pair of electrode leads 15 and 15, and a plurality of sealing members 16 and 22.

The semiconductor laser element 12 is sandwiched between a pair of submounts 18 and 18, along with a dummy bar 17. The pair of submounts 18 and 18 are sandwiched between the pair of heat sinks 13 and 13, along with the sealing member 16. The pair of heat sinks 13 and 13 are sandwiched between the pair of spacers 14 and 14, along with the electrode leads 15 and 15 and the sealing members 16.

A spacer 19 for eliminating a thickness difference between the electrode lead 15 and the sealing member 16 overlaps the electrode lead between the upper heat sink 13 and the upper spacer 14. A spacer 19 does not overlap the electrode lead 15 between the lower heat sink 13 and the lower spacer 14, and a step portion 20 corresponding to a thickness difference between the electrode lead 15 and the sealing member 16 is provided on the lower spacer 14 to correspond to a disposition region of the electrode lead 15. The pair of spacers 14 and 14 are sandwiched between a pair of sealing members 22 and 22. The pair of sealing members 22 and 22 are members at both ends in the Z direction of the structure 11. The pair of sealing members 22 and 22 are sandwiched between the bottom plate 3 and the top plate 5 of the holder 2.

In the present embodiment, a quantum cascade laser (QCL) element 21 is provided as an example of the semiconductor laser element 12. The quantum cascade laser element 21 has an active layer and a resonator structure for light of a predetermined wavelength generated by the active layer. The quantum cascade laser element 21 has a pair of end surfaces provided to face each other in a resonance direction of a resonator. A reflective film is provided on each of the pair of end surfaces. The reflective film on one end surface is formed of, for example, an Au film. The reflectance of the reflective film for laser oscillation light oscillated inside the resonator is, for example, 40% or more and 99% or less. The reflective film on the other end surface is formed of, for example, an Au film. The reflectance of the reflective film for laser oscillation light oscillated inside the resonator is higher than the reflectance of the reflective film on the one end surface. Accordingly, the laser oscillation light oscillated inside the resonator is emitted from one end surface side to the outside as the laser light L.

A resonator length of the quantum cascade laser element 21 is, for example, approximately several times a resonator length of a GaAs-based semiconductor laser element or the like. The resonator length of the GaAs-based semiconductor laser is, for example, approximately 0.5 mm, whereas the resonator length of the quantum cascade laser element 21 is, for example, approximately 3 mm. In the quantum cascade laser element 21, an operation mode that most efficiently extracts light output is quasi continuous wave (QCW) drive with short pulses and high repetition rate. In order to realize the operation mode, it is important to inject current pulses with relatively fast rise time into the quantum cascade laser element 21 with low loss.

The spacer 14 is a member that adjusts the length in the Z direction of the structure 11. The upper spacer 14 and the lower spacer 14 are made of, for example, copper and have a rectangular shape. When viewed in the Z direction, the upper spacer 14 and the lower spacer 14 have a rectangular shape with short sides in the X direction and long sides in the Y direction. The thicknesses in the Z direction of the upper spacer 14 and the lower spacer 14 are sufficiently larger than the thickness in the Z direction of the heat sink 13. In the present embodiment, the thicknesses in the Z direction of the upper spacer 14 and the lower spacer 14 are equal to each other except for the location of the step portion 20 described above. The thicknesses in the Z direction of the upper spacer 14 and the lower spacer 14 may be different from each other.

The heat sink 13 is a so-called microchannel-type heat sink in which flow paths of the cooling fluid are internally formed up to the vicinity of a heat generating body to be cooled. In addition, the heat sink 13 is a spray-type heat sink that sprays the cooling fluid toward the heat generating body directly below the heat generating body. The spray type is a type that utilizes the principle of a water gun. In this type, flow paths with relatively large cross-sectional area, which extend up to directly below the heat generating body, are used and the cooling fluid is sprayed from the spray holes provided directly below the heat generating body, toward the heating generating body. A detailed configuration of the heat sink 13 will be detailed later.

The electrode lead 15 is a portion that inputs a drive signal to the quantum cascade laser element 21, and is electrically connected to the quantum cascade laser element 21. The electrode lead 15 has, for example, a thin plate shape having approximately the same width as the width (width in the Y direction) of the submount 18. A proximal end side of the electrode leads 15 is led out from the structure 11 in a direction opposite the emission direction of the laser light L in the X direction. A distal end side of the electrode leads 15 is located between the pair of heat sinks 13 and 13 and the pair of spacers 14 and 14 in the structure 11, and the electrode lead 15 and the quantum cascade laser element 21 are disposed close to each other in the structure 11. Accordingly, for example, current pulses having a rise time of 50 ns or less can be injected to the quantum cascade laser element 21 with low loss.

The sealing members 16 are members that seal a gap between the pair of heat sinks 13 and 13 and a gap between the heat sink 13 and the spacer 14. Each sealing member 16 is, for example, formed in a thin plate shape by a silicone rubber. When viewed in the Z direction, each sealing member 16 has a rectangular shape with short sides in the X direction and long sides in the Y direction. The thickness in the Z direction of each sealing member 16 is, for example, approximately the same as the thickness in the Z direction of the pair of submounts 18 and 18 in a state where the submounts 18 and 18 hold the quantum cascade laser element 21. The length of the long sides of each sealing member 16 is smaller than the length of the long sides of the spacer 14. Each sealing member 16 is interposed between the pair of heat sinks 13 and 13 in a space excluding a disposition portion for the quantum cascade laser element 21 and between the heat sink 13 and the spacer 14 in a space excluding a disposition portion for the electrode leads 15 and 15.

Similarly to the sealing members 16, the sealing members 22 are, for example, formed in a thin plate shape by a silicone rubber. When viewed in the Z direction, the sealing members 22 have a rectangular shape with short sides in the X direction and long sides in the Y direction. The thickness in the Z direction of the sealing members 22 is approximately the same as the thickness in the Z direction of the sealing members 16. The shape of the sealing members 22 when viewed in the Z direction is identical to the shape of the spacers 14 when viewed in the Z direction. Each sealing member 22 is interposed between the lower spacer 14 and the bottom plate 3 and between the upper spacer 14 and the top plate 5.

Each of the sealing members 16 and 22 except for the sealing member 22 between the upper spacer 14 and the top plate 5, and each of the heat sinks 13 and 13 and the lower spacer 14 are provided with a supply port 32 forming a supply pipe 31 (refer to FIG. 3) for supplying the cooling fluid R into the structure 11 and with a discharge port 34 forming a discharge pipe 33 (refer to FIG. 3) for discharging the cooling fluid R from the structure 11. The supply ports 32 have circular cross-sections with the same diameter and the discharge ports 34 have circular cross-sections with the same diameter, and the supply ports 32 and the discharge ports 34 penetrate through the respective members in the Z direction. Each supply port 32 and each discharge port 34 are disposed apart from each other in the Y direction, and each supply port 32 is located closer to a quantum cascade laser element 21 side than each discharge port 34 when viewed in the Z direction.

In the structure 11, the supply pipe 31 and the discharge pipe 33 are formed by disposing the sealing members 16, the heat sinks 13 and 13, and the lower spacer 14 in the Z direction in a state where the positions of each supply port 32 and each discharge port 34 are aligned. The supply pipe 31 and the discharge pipe 33 communicate with the supply port and the discharge port of the bottom plate 3 of the holder 2, and can supply the cooling fluid R from the outside and discharge the cooling fluid R to the outside. By interposing each sealing member 16 between the pair of heat sinks 13 and 13 and between the heat sink 13 and the spacer 14, the cooling fluid R is prevented from leaking from the inside of the structure 11.

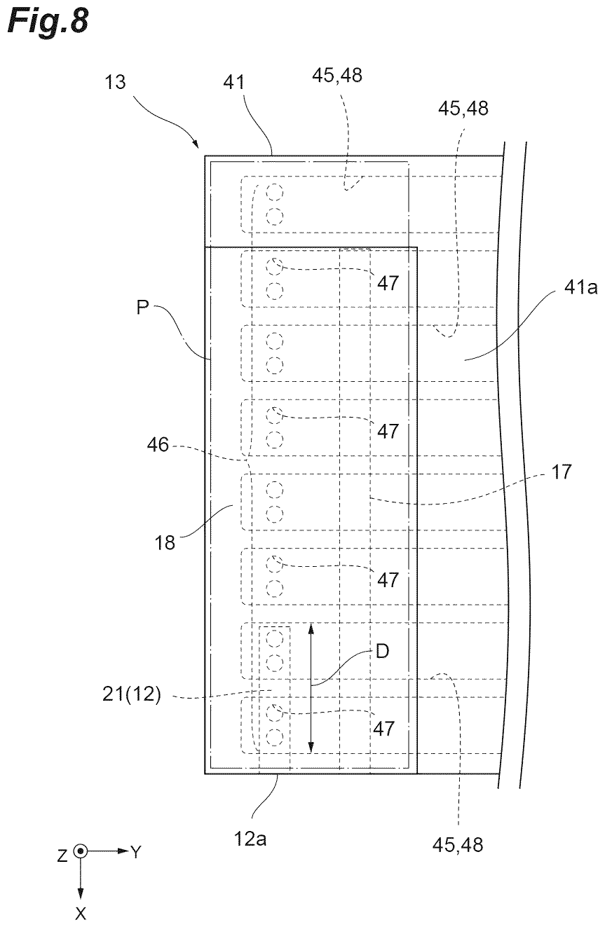

As illustrated in FIG. 3, the cooling fluid R supplied into the structure 11 through the supply pipe 31 is supplied into each of the pair of heat sinks 13 and 13. Inside the heat sinks 13 and 13, the cooling fluid R is sprayed from the spray holes 46 (refer to FIG. 8) directly below the quantum cascade laser element 21, to cool the quantum cascade laser element 21 located between the pair of heat sinks 13 and 13. The cooling fluid R used to cool the quantum cascade laser element 21 is discharged from the inside of the pair of heat sinks 13 through the discharge pipe 33 to the outside of the structure 11.

A positioning hole 35 is provided in each sealing member 16 and each of the pair of heat sinks 13 and 13 and the pair of spacers 14 and 14. Each positioning hole 35 has a circular cross-section with a smaller diameter than those of each supply port 32 and each discharge port 34, and penetrates through the corresponding member in the Z direction. Each positioning hole 35 is located midway between each supply port 32 and each discharge port 34 in the Y direction. By inserting a positioning member such as a pin into each positioning hole 35, each member is easily positioned when each sealing member 16, the pair of heat sinks 13 and 13, and the pair of spacers 14 and 14 are stacked.

Subsequently, a configuration of the heat sinks 13 described above and a disposition relationship between the heat sinks 13 and the quantum cascade laser element 21 will be described in detail.

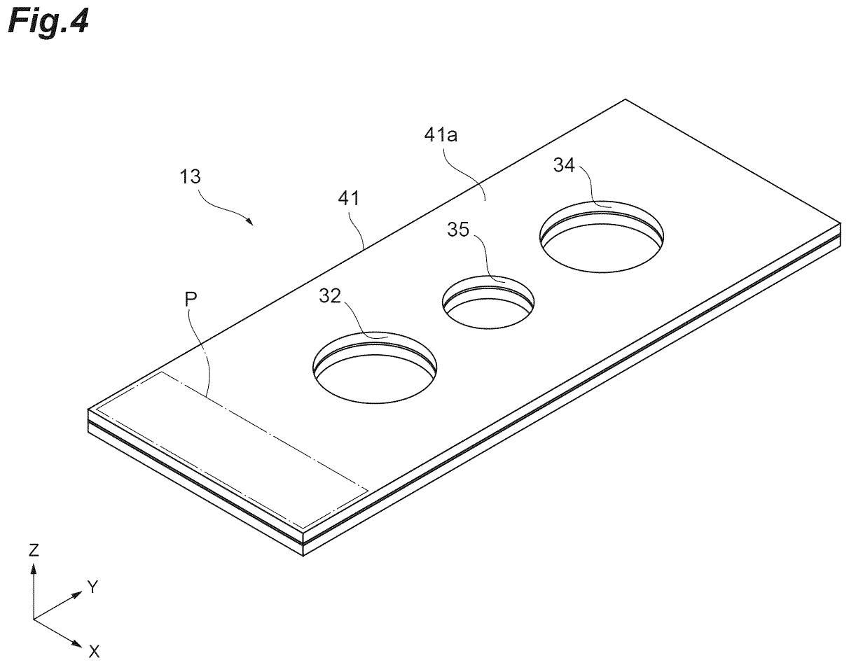

FIG. 4 is a perspective view of the heat sink. As illustrated in the same drawing, the heat sink 13 includes a body portion 41, for example, having a thin plate shape and made of copper. When viewed in the Z direction, the body portion 41 has a rectangular shape with short sides in the X direction and long sides in the Y direction. The length of the short sides and the length of the long sides of the body portion 41 coincide with the length of the short sides and the length of the long sides of the upper spacer 14 and the lower spacer 14, respectively. The thickness in the Z direction of the body portion 41 may be, for example, approximately the same as the thickness in the Z direction of each sealing member 16, and may be larger than the thickness in the Z direction of each sealing member 16. The body portion 41 is provided with each of the supply port 32, the discharge port 34, and the positioning hole 35 described above. The supply port 32, the discharge port 34, and the positioning hole 35 are formed to penetrate through the body portion 41 in the Z direction.

A disposition region P of the quantum cascade laser element 21 is provided on one end surface 41a in the Z direction of the body portion 41. When viewed in the Z direction, the disposition region P is provided with a constant width along an edge on one short side of the body portion 41, and extends from an edge on one long side of the body portion 41 toward an edge on the other long side. A supply path 45 that guides the cooling fluid R supplied from a supply port 32 side, toward the disposition region P, the spray holes 46 that spray the cooling fluid R guided by the supply path 45, from below the disposition region P, and a discharge path 48 that guides the cooling fluid R sprayed from the spray holes 46, toward the discharge port 34 are provided within the body portion 41.

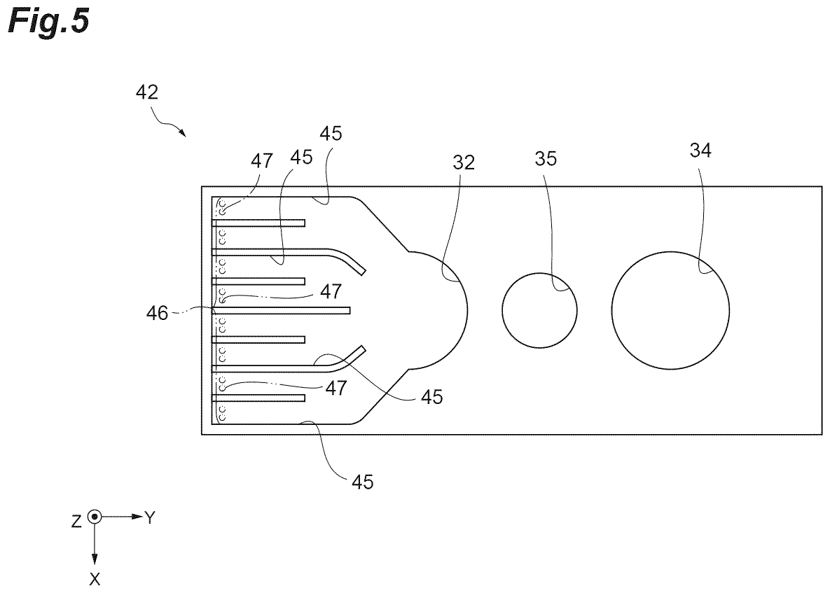

In forming the supply path 45, the spray holes 46, and the discharge path 48 as a series of flow paths within the body portion 41, as illustrated in FIGS. 5 to 7, the body portion 41 has a three-layer structure formed of a first layer 42, a second layer 43, and a third layer 44. The first layer 42 to the third layer 44 are, for example, plate-shaped members obtained by applying Ni plating and Au plating to surfaces of copper plates. For example, AuSn solder is used for joining the layers.

As illustrated in FIG. 5, the first layer 42 has a plurality of the supply paths 45. In the example of FIG. 5, four supply paths 45 are connected to the supply port 32. The four supply paths 45 extend from the supply port 32 toward the one short side in the Y direction while being deployed in the X direction. Each of the supply paths 45 branches into two on the way toward the one short side, and eight supply paths 45 extend in the Y direction on the one short side. Distal ends of the eight supply paths 45 extend to a position that overlaps the disposition region P when viewed in the Z direction, and are aligned with each other slightly inside the edge on the one short side.

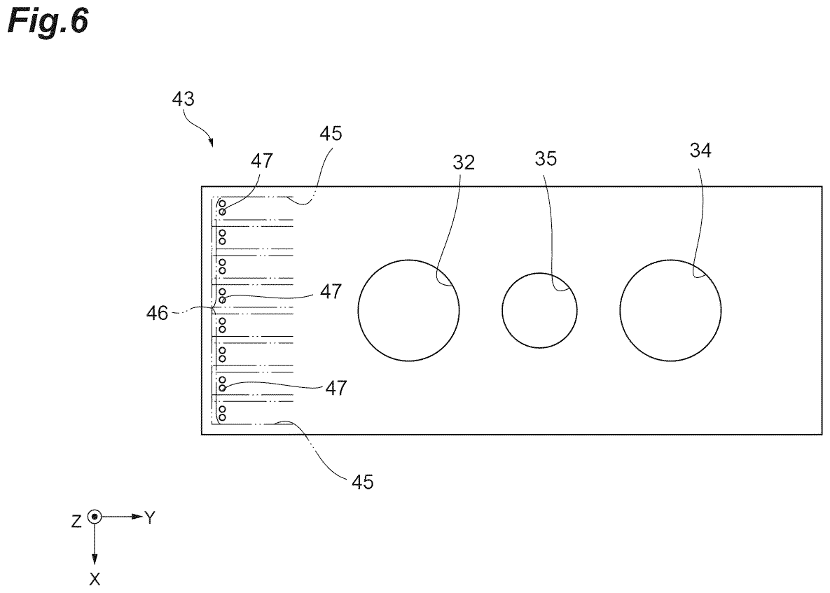

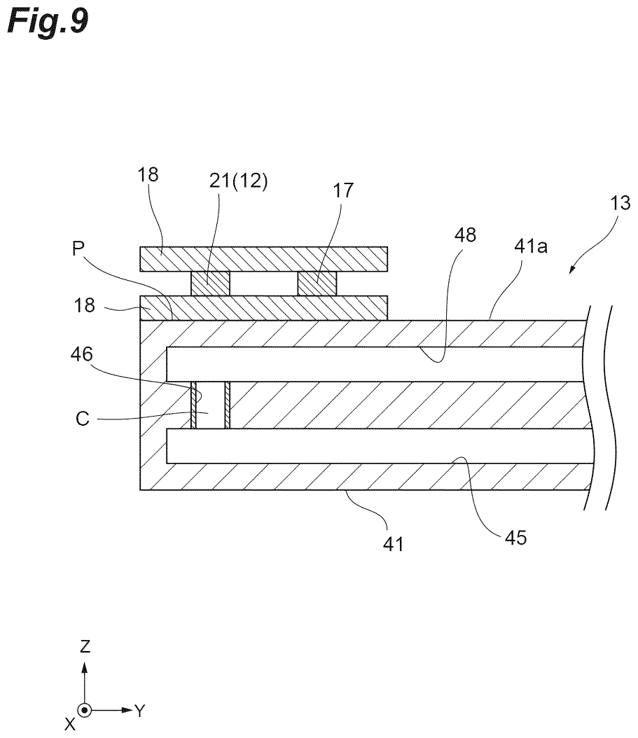

As illustrated in FIG. 6, the second layer 43 has the plurality of spray holes 46. Here, each of the plurality of spray holes 46 is formed of a round hole 47, and has a cross-sectional area sufficiently smaller than the cross-sectional area of each of the eight supply paths 45. The plurality of spray holes 46 are disposed to overlap the distal ends of the eight supply paths 45 when viewed in the Z direction. In the example of FIG. 6, two spray holes 46 communicate with the distal end of one supply path 45, and a total of 16 spray holes 46 are arranged along one short side in the X direction. A gold plating C (refer to FIG. 9) is applied to an entire surface of the inner wall of each spray hole 46. It is sufficient if the spray holes 46 spray the cooling fluid R from below the disposition region P, and may not be necessarily located directly below the quantum cascade laser element 21. A certain deviation between the quantum cascade laser element 21 and the spray holes 46 is allowable as long as cooling effect by the cooling fluid R is effective.

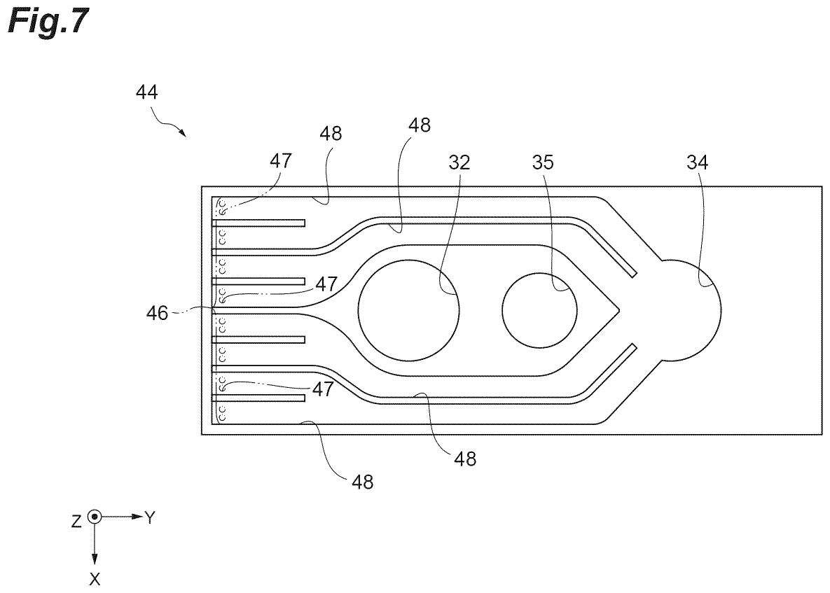

As illustrated in FIG. 7, the third layer 44 has a plurality of the discharge paths 48. In the example of FIG. 7, four discharge paths 48 are connected to the discharge port 34. The four discharge paths 48 extend from the discharge port 34 toward the one short side in the Y direction so as to bypass the supply port 32 and the positioning hole 35. Each of the discharge paths 48 branches into two on the way toward the one short side, and eight discharge paths 48 extend in the Y direction on the one short side. Distal ends of the eight discharge paths 48 extend to a position that overlaps the disposition region P when viewed in the Z direction, and are aligned with each other slightly inside the edge on the one short side. In the example of FIG. 7, two spray holes 46 communicate with the distal end of one discharge path 48.

FIG. 8 is a main part enlarged plan view illustrating a disposition relationship between the heat sink and the semiconductor laser element. FIG. 9 is a main part enlarged cross-sectional view thereof. As illustrated in FIGS. 8 and 9, the quantum cascade laser element 21 and the dummy bar 17 sandwiched between the pair of submounts 18 and 18 are disposed in the disposition region P on the body portion 41 of the heat sink 13.

When viewed in the Z direction, the submounts 18 have a rectangular shape with long sides in the X direction and short sides in the Y direction. Edges on one short side of the submounts 18 are aligned with the edge on the one long side of the body portion 41 in the disposition region P. Edges on one long side of the submounts 18 are aligned with the edge on the one short side of the body portion 41 in the disposition region P. In the present embodiment, the length of the long sides of each submount 18 is smaller than the length of the short side of the body portion 41. For this reason, when viewed in the Z direction, the submounts 18 overlap the first to seventh supply paths 45 and the first to seventh discharge paths 48 from the one long side of the body portion 41.

The quantum cascade laser element 21 is sandwiched between the submounts 18 and 18 such that the emitting surface 12a of the laser light L is aligned with the edge of the long side on one side of the body portion 41. When viewed in the Z direction, the quantum cascade laser element 21 is disposed at a position that overlaps the spray holes 46. In the example of FIG. 8, the quantum cascade laser element 21 overlaps the first and second supply paths 45 and the first and second discharge paths 48 from the one long side of the body portion 41, and is located directly above four spray holes 46 corresponding to the supply paths 45 and the discharge paths 48.

A resonance direction D of the quantum cascade laser element 21 coincides with the emission direction of the laser light L, and extends along the one short side of the body portion 41. Therefore, when viewed in the Z direction, the spray holes 46 of the heat sink 13 are disposed along the resonance direction D of the quantum cascade laser element 21 disposed in the disposition region P. In addition, when viewed in the Z direction, the supply paths 45 and the discharge paths 48 extend in a direction intersecting with the resonance direction D of the quantum cascade laser element 21 disposed in the disposition region P. In the example of FIG. 8, the resonance direction D of the quantum cascade laser element 21 extends along the X direction, and the plurality of spray holes 46 are arranged in the X direction parallel to the resonance direction D of the quantum cascade laser element 21. In addition, the supply paths 45 and the discharge paths 48 extend in the Y direction orthogonal to the resonance direction D of the quantum cascade laser element 21.

When viewed in the X direction, the dummy bar 17 has the same shape as that of the quantum cascade laser element 21, and is arranged apart from the quantum cascade laser element 21 in the Y direction between the submounts 18 and 18. The dummy bar 17 extends in the resonance direction of the quantum cascade laser element 21. In the example of FIG. 8, the dummy bar 17 extends in the X direction parallel to the resonance direction D of the quantum cascade laser element 21, with a length equal to the length of the long sides of the submounts 18. An extending direction of the dummy bar 17 is parallel to an arrangement direction of the plurality of spray holes 46, and is orthogonal to an extending direction of the supply paths 45 and the discharge paths 48.

As described above, in the semiconductor laser device 1, the spray holes are disposed along the resonance direction D of the quantum cascade laser element 21 disposed in the disposition region P. For this reason, even when the resonator length of the quantum cascade laser element 21 is relatively long, the cooling fluid R can be sprayed from the spray holes 46 toward the disposition region P with a length corresponding to the resonator length. In addition, in the semiconductor laser device 1, the discharge paths 48 extend in the direction intersecting with the resonance direction D of the quantum cascade laser element 21 disposed in the disposition region P. Accordingly, the distance by which the cooling fluid R, which has received heat from the disposition region P, flows below the disposition region P can be kept small. Therefore, in the semiconductor laser device 1, the cooling efficiency of the quantum cascade laser element 21 by the heat sinks 13 is improved.

In the present embodiment, the heat sinks 13 have a rectangular shape with long sides and short sides when viewed in the Z direction, and the resonance direction D of the quantum cascade laser element 21 disposed in the disposition region P extends along the short sides of the heat sinks 13. By aligning the resonance direction D of the quantum cascade laser element 21 with the short sides of the heat sinks 13, the structure of disposition of the quantum cascade laser element 21 with respect to the heat sinks 13 can be simplified. In addition, relatively large space can be secured in the long side direction of the heat sinks 13, and even when the resonator length is lengthened as in the quantum cascade laser element 21, a disposition space for the sealing members 16 that seal the flow paths of the cooling fluid R, or the like can be easily secured.

In the present embodiment, the spray holes 46 are formed of a plurality of the round holes 47. Accordingly, the pressure of the cooling fluid R to be sprayed from the spray holes 46 can be sufficiently increased, and the cooling efficiency of the quantum cascade laser element 21 can be further improved. In addition, in the present embodiment, the gold plating C is applied to the inner wall of each spray hole 46. The application of the gold plating C can prevent the ionization of the inner walls of the spray holes 46 caused by the cooling fluid R. Accordingly, the pressure of the cooling fluid R to be sprayed from the spray holes 46 can be prevented from decreasing due to an increase in the diameter of the spray holes 46 over time.

In the present embodiment, when viewed in the Z direction, the supply paths 45 extend in a direction intersecting with a disposition direction of the spray holes 46. When the supply paths extend along the disposition direction of the spray holes, it is considered that the pressure of the cooling liquid to be sprayed from the spray holes located on a distal end side of the supply paths is weaker than the pressure of the cooling liquid to be sprayed from the spray holes located on the proximal end side of the supply paths. By causing the supply paths 45 to extend in the direction intersecting with the disposition direction of the spray holes 46, the pressure of the cooling fluid R to be sprayed from the spray holes 46 is made uniform.

In the present embodiment, in the structure 11, the spacers 14 and 14 disposed adjacent to the heat sinks 13 are provided. Then, the electrode lead 15 electrically connected to the quantum cascade laser element 21 is disposed between the heat sink 13 and the spacer 14. According to such a configuration, since the electrode lead 15 can be disposed close to the quantum cascade laser element 21, current pulses with a fast rise time can be injected to the quantum cascade laser element 21 with low loss. Therefore, a short-pulse operation of the quantum cascade laser element 21 can be realized, and the extraction efficiency of light output in the quantum cascade laser element 21 can be increased.

In the present embodiment, the dummy bar 17 is disposed between the pair of submounts 18 and 18 alongside the quantum cascade laser element 21 disposed in the disposition region P. The dummy bar 17 extends in the resonance direction D of the quantum cascade laser element 21. The stability of the posture of the heat sinks 13, the spacers 14, or the like in the structure 11 can be increased by the disposition of the dummy bar 17.

In the present embodiment, the semiconductor laser element 12 is the quantum cascade laser element 21. According to the configuration of the semiconductor laser device 1, even when the quantum cascade laser element 21 having relatively long resonator length and relatively large amount of heat generated is disposed in the disposition region P, cooling by the heat sinks 13 can be efficiently performed.

The present disclosure is not limited to the embodiment. For example, in the embodiment, the quantum cascade laser element 21 has been provided as an example of the semiconductor laser element 12; however, the semiconductor laser element 12 disposed in the disposition region P may be any other semiconductor laser element, such as a GaAs-based semiconductor laser element, with a shorter resonator length or a less amount of heat generated than that of the quantum cascade laser element 21. According to the configuration of the semiconductor laser device 1, even when such other semiconductor laser element is disposed in the disposition region P, cooling by the heat sinks 13 can be efficiently performed.

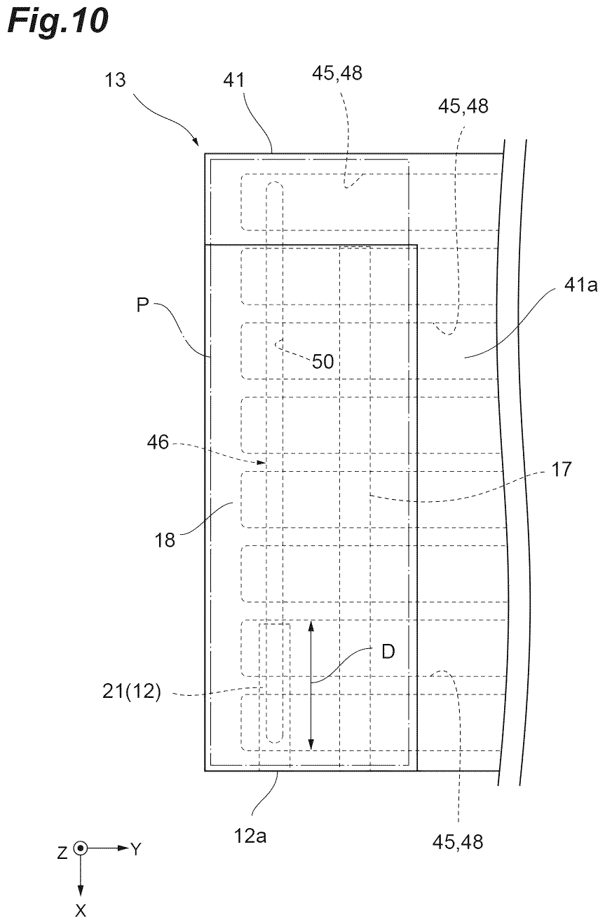

In the embodiment, the spray holes 46 are formed of the plurality of round holes 47; however, as illustrated in FIG. 10, the spray holes 46 may be formed of elongated holes 50. In the example of FIG. 10, the width in the Y direction of the elongated holes 50 is approximately the same as the diameter of the round holes 47 described above. An extending direction of the elongated holes 50 viewed in the Z direction is along the resonance direction D of the quantum cascade laser element 21 disposed in the disposition region P. In addition, the extending direction of the elongated holes 50 viewed in the Z direction is orthogonal to the extending direction of the supply paths 45 and the discharge paths 48. Even in such a mode, similarly to the embodiment, cooling efficiency of the quantum cascade laser element 21 by the heat sinks 13 is improved.

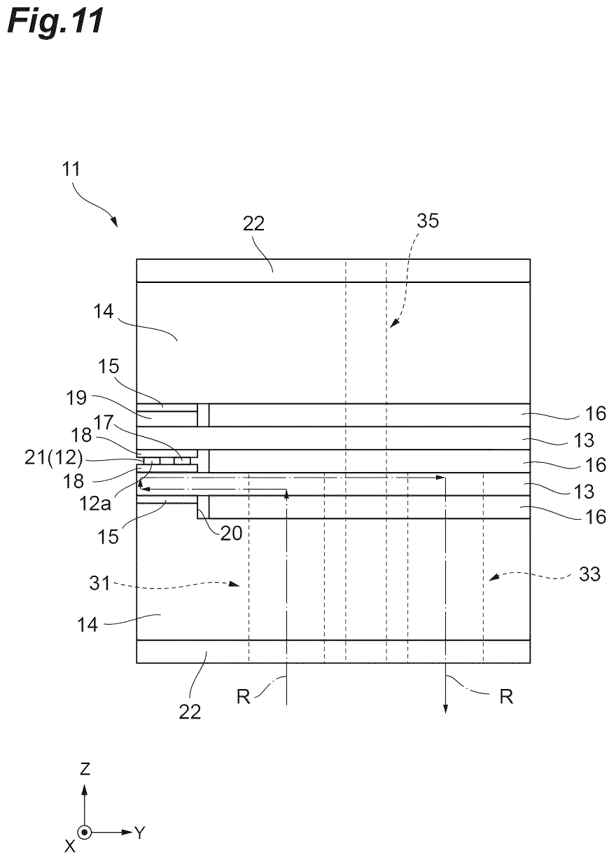

In the embodiment, the cooling fluid R supplied into the structure 11 through the supply pipe 31 is supplied into each of the pair of heat sinks 13 and 13; however, as illustrated in FIG. 11, the mode may be such that the cooling fluid R is supplied into only one heat sink 13. In the example of FIG. 11, only the positioning hole 35 is provided in each of the sealing members 16 between the heat sinks 13 and 13, the upper heat sink 13, and the sealing member 16 between the upper heat sink 13 and the upper spacer 14. The cooling fluid R supplied from the supply pipe 31 into the structure 11 is supplied into only the lower heat sink 13. Even in such a mode, similarly to the embodiment, cooling efficiency of the quantum cascade laser element 21 by the heat sinks 13 is improved.

### REFERENCE SIGNS LIST

1: semiconductor laser device, 12: semiconductor laser element, 13: heat sink, 14: spacer, 15: electrode lead, 17: dummy bar, 21: quantum cascade laser element, 32: supply port, 34: discharge port, 41: body portion, 45: supply path, 46: spray hole, 47: round hole, 48: discharge path, C: gold plating, D: resonance direction, P: disposition region, R: cooling fluid.

1. A semiconductor laser device comprising:
a semiconductor laser element; and
a heat sink configured to cool the semiconductor laser element,
wherein the heat sink includes a body portion which has a surface with a disposition region where the semiconductor laser element is disposed, and in which a supply port for supplying a cooling fluid and a discharge port for discharging the cooling fluid are provided apart from the disposition region,
a supply path configured to guide the cooling fluid supplied from a supply port side, toward the disposition region, spray holes that spray the cooling fluid guided by the supply path, from below the disposition region, and a discharge path configured to guide the cooling fluid sprayed from the spray holes, toward the discharge port are provided within the body portion,
in a plan view of the heat sink, the spray holes are disposed along a resonance direction of the semiconductor laser element disposed in the disposition region, and
in a plan view of the heat sink, the discharge path extends in a direction intersecting with the resonance direction of the semiconductor laser element disposed in the disposition region.

2. The semiconductor laser device according to claim 1,
wherein the heat sink has a rectangular shape having long sides and short sides in a plan view, and
the resonance direction of the semiconductor laser element disposed in the disposition region extends along the short sides of the heat sink.

3. The semiconductor laser device according to claim 1,
wherein the spray holes are formed of a plurality of round holes.

4. The semiconductor laser device according to claim 1,
wherein a gold plating is applied to an inner wall of each spray hole.

5. The semiconductor laser device according to claim 1,
wherein in a plan view of the heat sink, the supply path extends in a direction intersecting with a disposition direction of the spray holes.

6. The semiconductor laser device according to claim 1,
wherein a spacer disposed adjacent to the heat sink is provided, and
an electrode lead electrically connected to the semiconductor laser element is disposed between the heat sink and the spacer.

7. The semiconductor laser device according to claim 1,
wherein a dummy bar disposed alongside the semiconductor laser element disposed in the disposition region and extending in the resonance direction of the semiconductor laser element is provided.

8. The semiconductor laser device according to claim 1,
wherein the semiconductor laser element is a quantum cascade laser element.
